(19) United States
(12) Patent Application Publication
(10) Pub. No.: US 2004/0027181 A1
(43) Pub. Date: Feb. 12, 2004

(54) Clock multiplying PLL circuit

(75) Inventor: Hideaki Watanabe, Kasugai (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/606,225

(22) Filed: Jun. 26, 2003

(30) Foreign Application Priority Data
Jun. 28, 2002 (JP) 2002-189084

(51) Int. Cl. H03L 7/06

(52) U.S. Cl. 327/156

(57) ABSTRACT

The present invention provides a clock multiplying PLL circuit capable of suppressing jitters with a simple configuration and shortening a lockup time. The clock multiplying PLL circuit (1) comprises a VCO (40) for outputting an output clock signal (ST), first through n-th dividers (51 through 5n) for dividing the output clock signal (ST) and thereby outputting first through n-th divided signals (SD1 through SDn), a DLL (60) for generating first through n-th reference clock signals (SB1 through SBn) different in phase from one another using a reference clock signal (SR), and first through n-th phase comparators (11 through 1n) for comparing phases of i-th reference clock signals (SBi) and i-th divided signals (SDi) (where i: an integer of 1 to n). An oscillation frequency of the output clock signal (ST) of the VCO (40) changes based on the results of comparisons by the first through n-th phase comparators (11 through 1n).

### CROSS-REFERENCE TO RELATED APPLICATIONS

This application is based upon and claims the benefit of priority from each of the prior Japanese Patent Application No. 2002-189084 filed on Jun. 28, 2002, the entire contents of which are incorporated herein by reference

### BACKGROUND OF THE INVENTION

1. Field of the Invention

The present invention relates to a clock multiplying PLL circuit for converting an input reference clock signal into an output clock signal having a multiplied frequency.

2. Description of the Related Art

There has been known a clock multiplying PLL circuit which makes use of an input reference clock signal and converts it to an output clock signal having a multiplied frequency. As such a clock multiplying PLL circuit, a clock multiplying PLL circuit 100 having a phase comparator 110, a charge pump 120, a low-pass filter (hereinafter also called simply “LPF”) 130, a voltage-controlled oscillator (hereinafter called “VCO”) 140, and a divider 150 is known as shown in FIG. 1 by way of example. In the clock multiplying PLL circuit 100, the phases of a divided signal SD of the divider 100 and a reference clock signal SR are compared by the phase comparator 110. A current corresponding to each of an up signal and a down signal corresponding to the result of phase comparison is outputted from the charge pump 120 and integrated by the LPF 130 from which it is produced as a voltage output. The voltage output is inputted to the VCO 140 from which an output clock signal ST having a frequency corresponding to it is outputted. The divider 150 divides the output clock signal ST. Thus, an output clock signal ST having a multiplication number M corresponding to an inverse number of a dividing ratio (1/M) is outputted compared with the reference clock signal SR. The output clock signal ST is PLL-controlled by making a phase comparison by once every one cycle of the reference clock signal SR, so that the accuracy of its frequency is maintained.

Since, however, the output clock signal ST is PLL-controlled by making the phase comparison for each cycle of the reference clock signal SR as described above, PLL-control on the output clock signal is carried out by making a phase comparison once per 1024 pulses, for example, as for the number of pulses of the output clock signal when the multiplication number M reaches a large value (e.g., several hundred times to several thousand times), so that a jitter of the output clock signal is apt to increase. Further, a lockup time also increases.

### SUMMARY OF THE INVENTION

The present invention has been made in view of the foregoing problem. Therefore, the present invention aims to provide a clock multiplying PLL circuit capable of suppressing jitters with a simple configuration and shortening a lockup time.

Thus, as means for solving the problem, there is provided a clock multiplying PLL circuit comprising an oscillator circuit for outputting an output clock signal, first through n-th dividers for dividing the output clock signal and thereby outputting first through n-th divided signals (where n: an integer greater than or equal to 2) respectively, the first through n-th dividers being different in effective transition timings of the outputted first through n-th divided signals from one another, a reference clock signal generating circuit for generating n types of first through n-th reference clock signals different in phase from one another by using an input reference clock signal, and first through n-th phase comparators for respectively comparing phases of the i-th reference clock signals and i-th divided signals (where i: an integer of 1 to n), wherein an oscillation frequency of the output clock signal outputted from the oscillator circuit is changed based on the results of comparisons by the first through n-th phase comparators.

The clock multiplying PLL circuit of the present invention includes n-pieces of dividers (first through n-th dividers), the n-pieces of phase comparators (first through n-th phase comparators) and the reference clock signal generating circuit for generating n types of reference clock signals (first through n-th reference clock signals). The oscillation frequency of the output clock signal outputted from the oscillator circuit is changed based on comparison results by respective n-pieces of phase comparators. Therefore, different from a conventional clock multiplying PLL circuit, the clock multiplying PLL circuit of the present invention is capable of making phase comparisons at a rate of n times for each cycle and performing PLL control without making a phase comparison at a rate of once for each cycle of the reference clock signal and carrying out PLL control. Thus, since the PLL control is relatively performed at frequent intervals, a jitter of the output clock signal can be reduced. Further, since the PLL control is frequently performed, a PLL control-based locked state can be achieved at an early stage after power-on, for example. Therefore, a lockup time can be also shortened.

Incidentally, the effective transition timing in the present specification means an effectively-handled signal transition timing of signal transition timings each provided to cause a signal to transition (rise) from a low level to a high level since level inversion of the signal or to cause the signal to transition (fall) from the high level to the low level. When upon using a square-wave clock signal having a duty ratio of 50%, for example, some operation is performed using timing provided to raise the signal but no operation is done using a fall timing of the signal, such a rise timing of the rise and fall timings of the signal results in an effective transition timing. When some operation is performed using the fall timing of the signal but no operation is done using the rise timing of the signal in reverse, the fall timing results in effective transition timing. When some operation is performed using the rise timing of the signal whereas some operation is also performed using the fall timing of the signal, both the rise timing and the fall timing result in effective transition timings.

As such a configuration as to change the oscillation frequency of the output clock signal outputted from the oscillator circuit, based on the results of comparisons by the first through n-th phase comparators, any configuration may be adopted wherein the oscillation frequency of the oscillator circuit is changed based on the result of comparison by the corresponding phase comparator to thereby enable PLL control. For example, such a known configuration that a voltage-controlled oscillator (VCO) is used as the oscillator circuit, and the result of comparison is inputted to the VCO via a charge pump and a low-pass filter, can be used. As the phase comparators, a so-called binary type phase comparator can be used in addition to a so-called linear type phase comparator. With this, such a circuit configuration as to change the oscillation frequency of the oscillator circuit can be suitably selected too.

Further, as another solving means, there is provided a clock multiplying PLL circuit for PLL-controlling an oscillator circuit and outputting an output clock signal having multiplied frequency obtained by multiplying an input reference clock signal, comprising n (where n: an integer greater than or equal to 2) dividers having the same dividing ratio and for dividing the output clock signal, n-pieces of phase comparators paired with the dividers, and a reference clock signal generating circuit for generating n types of reference clock signals different in phase from one another using the reference clock signal, wherein each of the phase comparators obtains a result of phase comparison from a phase comparison between each of divided signals outputted from the dividers paired with the phase comparators and any of the n types of reference clock signals, and the oscillator circuit is PLL-controlled by n times for each cycle period of the reference clock signal by use of the result of phase comparison.

The clock multiplying PLL circuit of the present invention includes the n-pieces of dividers, the n-pieces of phase comparators, and the reference clock signal generating circuit for generating n types of reference clock signals. An oscillation frequency of the output clock signal from the oscillator circuit is changed based on the results of phase comparisons by the n-pieces of phase comparators. Therefore, different from a conventional clock multiplying PLL circuit, the clock multiplying PLL circuit is capable of performing PLL control at a rate of n times for each cycle without performing PLL control at a rate of once for each cycle of the reference clock signal. Thus, since the PLL control is relatively carried out at frequent intervals, a jitter of the output clock signal can be reduced. Further, since the PLL control is frequently done, a PLL control-based locked state can be achieved at an early stage after power-on, for example. Therefore, a lockup time can be also shortened.

Furthermore, as further solving means, there is provided a clock multiplying PLL circuit for outputting an output clock signal having multiplied frequency obtained by multiplying an input reference clock signal, comprising an oscillator circuit, and a multiple control circuit for performing PLL-control on the oscillator circuit by a predetermined number of times greater than or equal to 2 for each cycle period of the reference clock signal.

The clock multiplying PLL circuit of the present invention performs PLL control at a rate of the predetermined number of times greater than or equal to 2 for each cycle, different from a conventional clock multiplying PLL circuit, without performing PLL control at a rate of once for each cycle of the reference clock signal. Thus, since the PLL control is relatively carried out at frequent intervals, a jitter of the output clock signal can be reduced. Further, since the PLL control is done frequently, a PLL control-based locked state can be achieved at an early stage after power-on, for example. Therefore, a lockup time can be also shortened.

The above and further objects and novel features of the invention will more fully appear from the following detailed description when the same is read in connection with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a block diagram showing a configuration of a conventional clock multiplying PLL circuit;

FIG. 2 is a block diagram illustrating a schematic configuration of a clock multiplying PLL circuit according to an embodiment of the present invention;

FIG. 3 is a block diagram depicting a configuration of the clock multiplying PLL circuit according to the embodiment;

FIG. 4 is a time chart showing changes in first through nth reference clock signals;

FIG. 5 is a time chart illustrating changes in first through n-th divided signals;

FIG. 6 is a time chart related to phase comparisons of the clock multiplying PLL circuit according to the embodiment; and

FIG. 7 is a block diagram of a configuration of the clock multiplying PLL circuit according to the embodiment and including divider initial reset means.

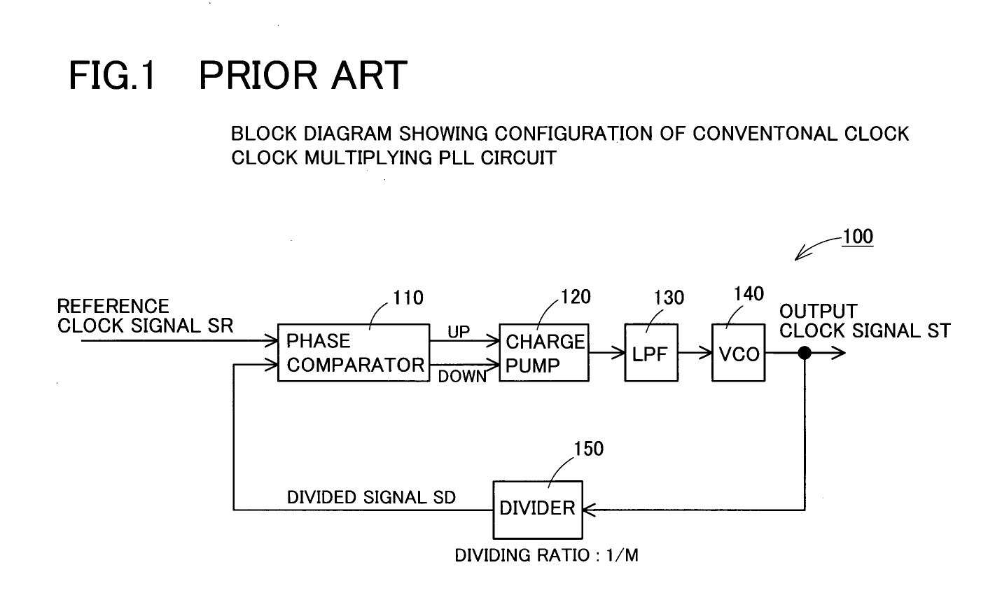

### DETAILED DESCRIPTION OF THE PREFERRED EMBODIMENTS

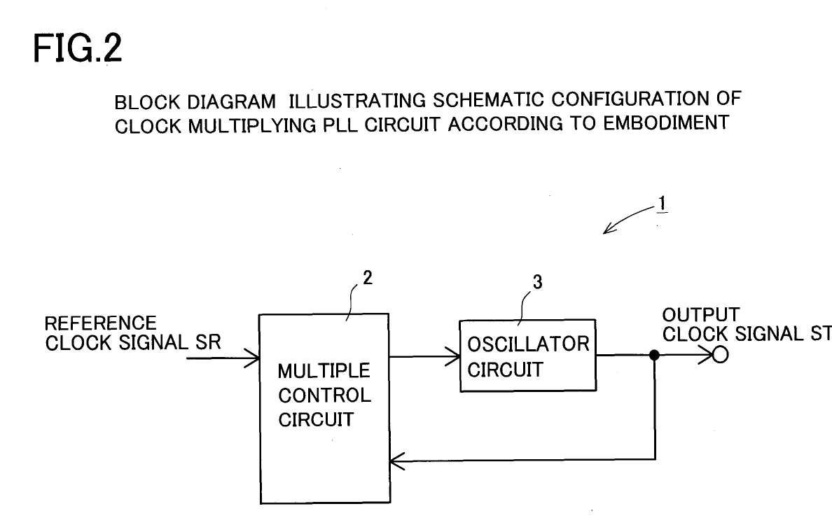

An embodiment of the present invention will be described with reference to FIGS. 2 through 7. Incidentally, the present embodiment might show an example in which n=8 and M=1024, in combination for the purpose of easy understanding.

FIG. 2 is a block diagram showing a schematic configuration of a clock multiplying PLL circuit 1 according to the present embodiment. The clock multiplying PLL circuit 1 according to the present embodiment multiplies frequency of a reference clock signal SR (where a multiplication number: M) and thereby outputs an output clock signal ST higher in frequency. The clock multiplying PLL circuit 1 has a multiple control circuit 2 and an oscillator circuit 3 controlled by the multiple control circuit 2. The multiple control circuit 2 is configured so as to perform PLL control on the oscillator circuit 3 n times within a period corresponding to one cycle of the reference clock signal SR. Namely, the conventional clock multiplying PLL circuit 100 has performed the PLL control once alone within the period corresponding to one cycle of the reference clock signal SR, whereas the present clock multiplying PLL circuit 1 is capable of performing the PLL control n times within the same period. It is therefore possible to suppress a jitter of the output clock signal ST. After power-on, for example, the PLL-controlled output clock signal can be outputted earlier. Namely, a lockup time can be also shortened.

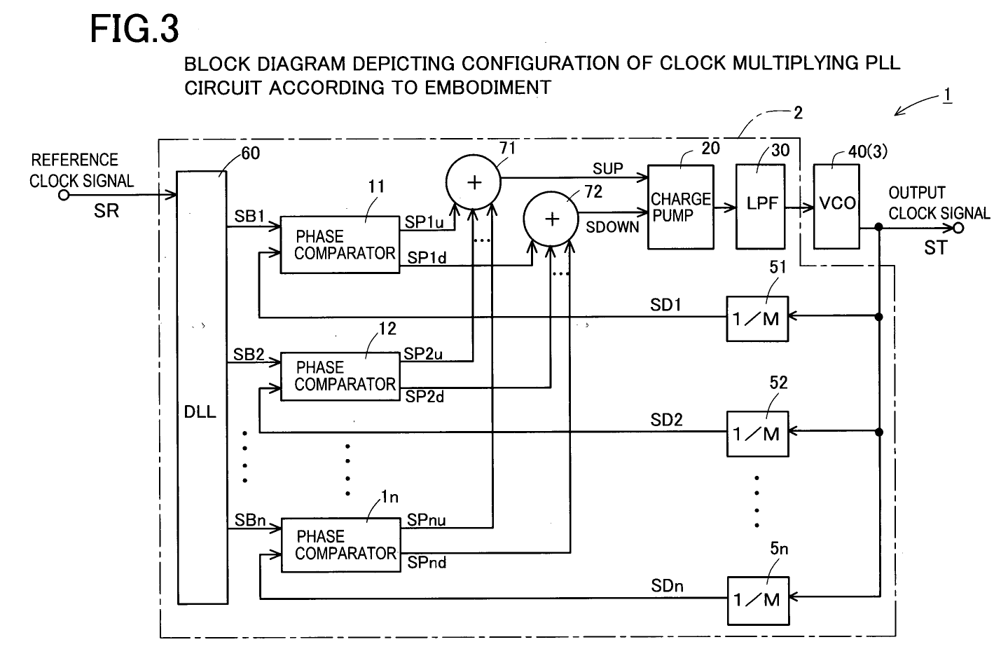

A configuration of the present clock multiplying PLL circuit 1 will next be described with reference to FIG. 3. Of the clock multiplying PLL circuit 1, the multiple control circuit 2 indicated by a dashed line comprises a charge pump 20, an LPF 30, first through n-th dividers 51 through 5n, n first through n-th phase comparators 11 through in, a delay locked loop (hereinafter called simply “DLL”) 60, and adders 71 and 72. Further, the oscillator circuit 3 is a VCO 40 whose oscillation frequency varies according to a voltage output of the LPF 30.

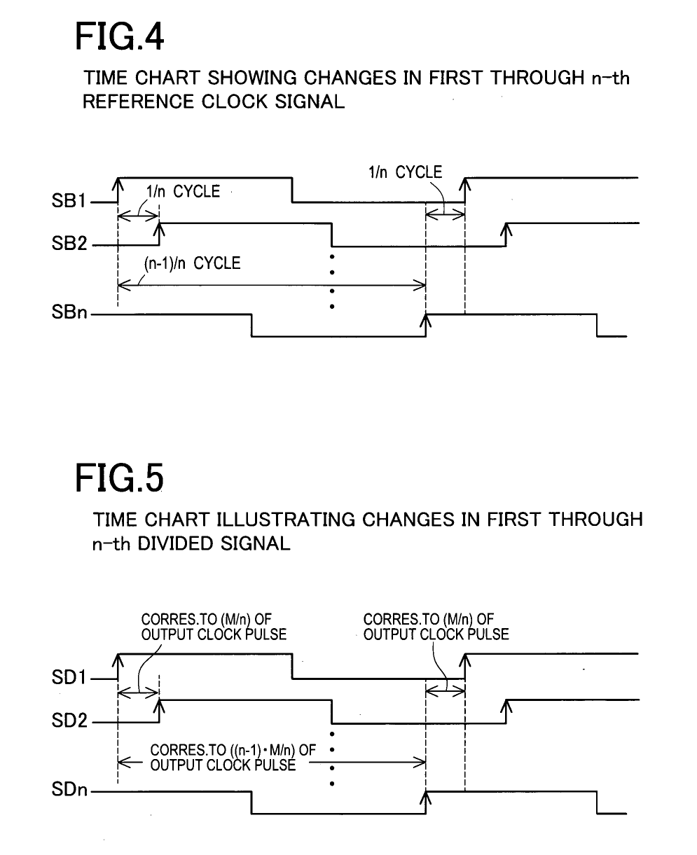

Here, the DLL 60 is a circuit for delaying the reference clock signal SR by a predetermined period when it is inputted, and generating n types of first through n-th reference clock signals SB1 through SBn different in phase from one another. Described specifically, as shown in FIG. 4, the DLL 60 generates the first reference clock signal SB1, generates the second reference clock signal SB2 delayed a 1/n cycle compared with the first reference clock signal SB1, and generates the n-th reference clock signal delayed a ((n−1)/n) cycle compared with the first reference clock signal SB1. Thus, the DLL 60 is a circuit which generates j-th reference clocks SBj (where j: an integer of 2 to n) delayed (j−1)/n cycles compared with the first reference clock signal SB1. When n=8, for example, the DLL 60 generates second through eighth reference clocks SB2 through SB8 delayed a 1/8 cycle, a 2/8 cycle, . . . , a 7/8 cycle. In the present embodiment as is understood from the above, any of the differences in phase between a given reference clock signal and respective reference clock signals each having a number adjacent thereto is expressed as a 1/n cycle (e.g., 1/8 cycle).

Although the DLL 60 is not described in detail, the respective reference clock signals SB1 through SBn are respectively controlled in delay time, accordingly, phase delay with high accuracy by the known delay locked loop control.

Incidentally, only signal rise timings of signal transition timings of the respective reference clock signals SB1 and the like are used as indicated by arrows ↑ in FIG. 4 in the present embodiment. Thus, in the present embodiment, only the signal rise timings are taken as effective transition timings of the respective reference clock signals SB1 and the like.

On the other hand, any of the n first through n-th dividers 51 through 5n has the same dividing ratio 1/M (e.g., 1/1024). They divide the output clock signal ST and respectively output first through n-th divided signals SD1 through SDn. The first through n-th divided signals SD1 through SDn respectively change (signal-transition) so as to rise each time the numbers of pulses of the output clock signals ST inputted to the respective dividers 51 through 5n respectively reach M (e.g., 1024).

Described further specifically, as shown in FIG. 5, the second divided signal SD2 rises with a delay of the number of pulses P=M/n of the output clock signal ST compared with the rise timing of the first divided signal SD1. Further, the n-th divided signal SBn rises with a delay of the number of pulses Pn=(n−1)·M/n of the output clock signal ST compared with the rise timing of the first divided signal SD1.

Thus, each of the j-th divided signals SBj (where j: an integer of 2 to n) rises with being delayed the number of pulses Pj=(j−1)·M/n of the output clock signal ST compared with the rise timing of the first divided signal SD1. Assuming that n=8 and M=1024, for example, P2=128, P3=256, . . . , P8=896 respectively. In other words, in the present embodiment as is understood from the above description, any of the given divided signal and the divided signals each having the number adjacent thereto is shifted M/n (e.g., 1025/8=128) in the number of pulses of the output clock signal ST.

Incidentally, only signal rise timings of signal transition timings of the respective divided signals SD1 and the like are used as indicated by arrows ↑ in FIG. 5 in the present embodiment. Thus, in the present embodiment, effective transition timings of the respective divided signals SD1 and the like are only the signal rise timings.

Further, as shown in FIG. 3, the first divided signal SD1 outputted from the first divider 51 and the first reference clock signal SB1 both set as a pair are inputted to the first phase comparator 11. Further, the n-th divided signal SDn outputted from the n-th divider and the n-th reference clock signal SBn both set as a pair are inputted to the n-th phase comparator in. Thus, the input i-th phase comparators 1i are respectively inputted with the i-th reference clock signals SBi and i-th divided signals SDi (where i: an integer of 1 to n).

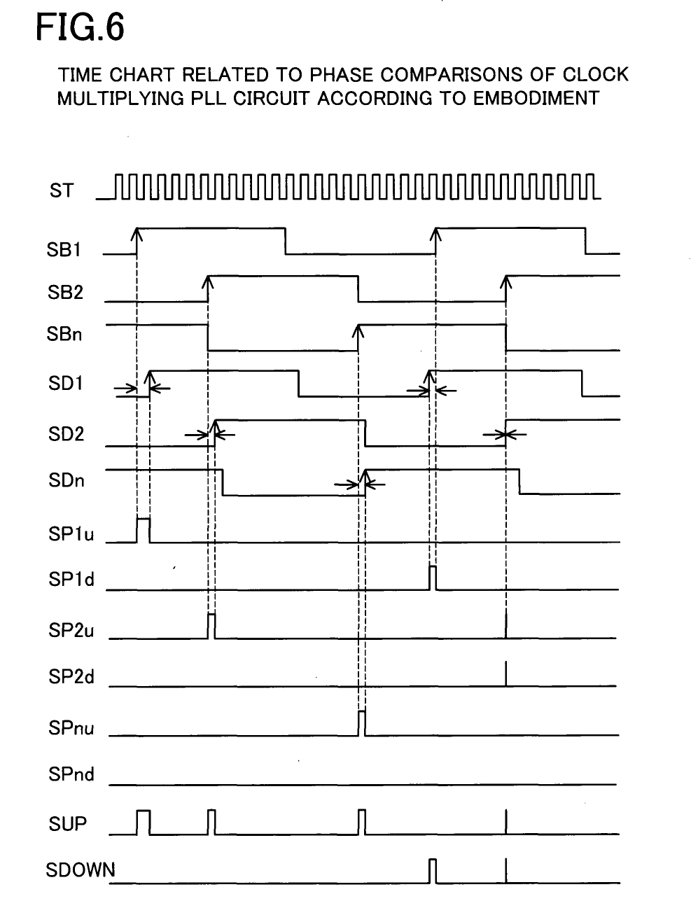

The first phase comparator 11 is of the known phase/frequency comparator, which outputs the result of comparison corresponding to the difference in phase between the rise timing (effective transition timing) of the input first reference clock signal SB1 and the rise timing (effective transition timing) of the input first divided signal SD1 with the rise timing of the first reference clock signal SB1 as the reference. Described specifically, when the first divided signal SD1 is delayed in phase compared with the first reference clock signal SB1, the first phase comparator 11 outputs a first up signal SP1u brought to a high level during a period equivalent to the phase delay. When the first divided signal SD1 is advanced in phase compared with the first reference clock signal SB1 in reverse, the first phase comparator 11 outputs a first down signal SP1d brought to a high level during a period equivalent to the phase lead (see FIG. 6).

Other phase comparators 12 through in are similar to the above. Namely, they respectively output up signals SP2u through SPnu or down signals SP2d through SPnd equivalent to the differences in phase between the rise timings of the input reference clock signals SB2 and the like and those of the input second divided signals SD2 and the like with the rise timings of the input reference clock signals SB2 and the like as the references.

The manner of these phase comparisons is shown in FIG. 6. It should however be borne in mind that the output clock signal ST shown in FIG. 6 is merely described to show that it has a sufficient high frequency as compared with the first reference clock signals SB1 and the like, and the relationship between the signal transition timings and the rise timings of the first divided signals SD1 and the like, and the multiplication number M or the like are not accurately described.

When the rise timing of the first divided signal SD1, which is indicated by an arrow ↑, is delayed compared with the rise timing of the first reference clock signal SB1, which is indicated by an arrow ↑ similarly, as shown on the right side in FIG. 6, the first up signal SP1u having a pulse width corresponding to its delay is outputted. On the other hand, when the rise timing of the first divided signal SD1, which is indicated by an arrow ↑, is earlier than the rise timing of the first reference clock signal SB1, which is indicated by the arrow ↑ similarly as shown on the left side in FIG. 6 (when the former leads the latter), the first down signal SP1d having a pulse width corresponding to its lead is outputted. Incidentally, when the rise timing of the first reference clock signal SB1 or the like to be compared and the rise timing of the fist divided signal SD1 or the like coincide with each other, the phase comparator 11 or the like employed in the present embodiment outputs both the extremely short first up signal SP1u or the like and first down signal SP1d or the like. Reference is made to such a case since it is illustrated by way of example on the right side in FIG. 6 by the second up signal SP2u and the second down signal SP2d.

Next, the results of these phase comparisons are added together by the adders 71 and 72. Described specifically, the first through n-th up signals SP1u through SPnu are added by the adder 71 to generate an up signal SUP. Further, the first through n-th down signals SP1d through SPnd are added by the adder 72 to generate a down signal SDOWN.

Thereafter, the present PLL circuit 1 is operated in a manner similar to the known clock multiplying PLL circuit 100. Namely, the charge pump 20 outputs a current corresponding to each of the up signal SUP and the down signal SDOWN, and the LPF 30 integrates (smoothes) it and provides the result of integration as a voltage output. The voltage output is inputted to the VCO 40 from which an output clock signal ST having a frequency corresponding to it is outputted.

When, for example, the rise timing of the first divided signal SD1 is slightly delayed from the rise timing of the first reference clock signal SB1 because the frequency of the output clock signal ST is slightly low, the first up signal SP1u is outputted and eventually the VCO 40 is controlled so that the frequency thereof rises slightly. In doing so, the differences in phase between the respective divided signals and the respective reference clock signals change in a lead direction. In its reverse case, the first down signal SP1d is outputted and the frequency of the VCO 40 is controlled so as to decrease. In doing so, the differences in phase between the respective divided signals and the respective reference clock signals change in a delay direction. Thus, the phase differences become small and the frequency of the output clock signal ST is PLL-controlled so as to always reach a suitable value. Besides, the first through n-th dividers 51 through 5n divide the output clock signal ST with a dividing ratio (1/M). Thus, an output clock signal ST having a multiplication number M (e.g., 1024 times) corresponding to the inverse number of the dividing ratio (1/M) is outputted with respect to the reference clock signal SR.

Further, the clock multiplying PLL circuit 1 according to the present embodiment phase-compares the reference clock signal SR and the first through n-th clock signals SB1 through SBn obtained by delaying it, n times by n times every one cycles thereof as can be easily understood if reference is made to the up signal SUP and down signal SDOWN shown in FIG. 6. According to the results of comparisons corresponding to the respective number of times, the output clock signal ST is PLL-controlled on a case-by-case basis. Namely, since the output clock signal ST is PLL-controlled n times by n times (e.g., by eight times) every one cycles of the reference clock signal SR, the frequency thereof is maintained with higher accuracy. Therefore, a jitter of the output clock signal ST can be reduced.

In the present embodiment in particular, the DLL 60 has produced the first through n-th reference clock signals SB1 through SBn with being shifted a 1/n cycle by a 1/n cycle. On the other hand, the first through n-th dividers 51 through 5n respectively generate the first through n-th divided signals SD1 through SDn with being shifted M/n by M/n with the number of pulses of the output clock signal ST. Therefore, the PLL-control timings provided for the output clock signal ST are made uniform and the jitter can be also reduced uniformly.

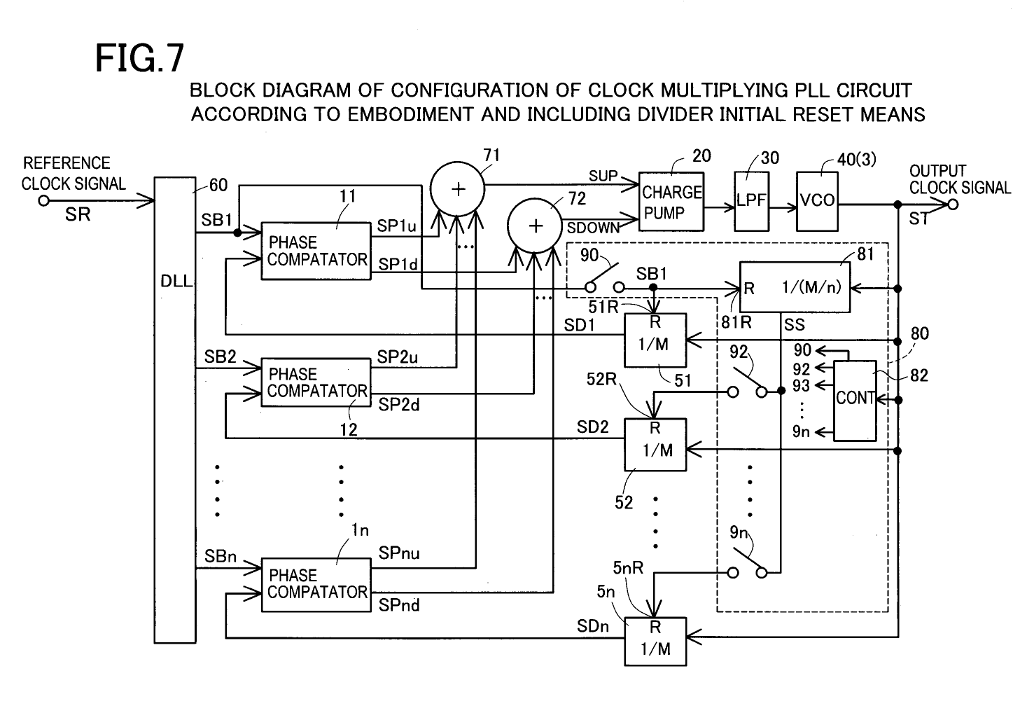

A description has already been made of the case in which the first through n-th divided signals SD1 through SDn of the first through n-th dividers 51 through 5n have been brought to the following relation, i.e., each of the j-th divided signals SBj (where j: an integer of 2 to n) rises with being delayed the number of the pulses Pj=(j−1)M/n of the output clock signal ST compared with the rise timing of the first divided signal SD1. In order to hold the dividers 51 through 5n in such a relationship, the clock multiplying PLL circuit 1 according to the present embodiment is provided with a divider initial reset circuit 80. The present divider initial reset circuit 80 and its reset method will be described with reference to FIG. 7.

The divider initial reset circuit 80 includes a reset divider 81, a switching control circuit 82, a reset switch 90 and n−1 selector switches 92 through 9n.

Of these, the reset divider 81 is a divider having a dividing ratio 1/(M/n). Assuming that n=8 and M=1024, for example, the present divider serves as a divider having a dividing ratio of 1/128. Namely, each time the reset divider 81 counts M/n (e.g., 128) in response to the number of pulses of the output clock signal ST, a reset signal SS corresponding to its divided signal changes so as to be rise timing. As will next be descried, the switch control circuit 82 controls the turning on and off of the reset switch 90 and the selector switches 92 through 9n. The reset switch 90 is a switch for turning on and off the input of the first reference clock signal SB1 to a reset terminal 51R of the first divider 51 and a reset terminal 81R of the reset divider 81 according to instructions issued from the switch control circuit 82. Further, the selector switches 92 through 9n are switches for respectively turning on and off the inputs of the reset signal SS corresponding to the divided signal of the reset divider 81 to reset terminals 52R through 5nR of the second through n-th dividers 52 through 5n according to instructions issued from the switching control circuit 82.

After the supply of a power supply to the clock multiplying PLL circuit 1 is started and the output clock signal ST is outputted from the VCO 40, the switch control circuit 82 turns on the reset switch 90 to input the first reference clock signal SB1 outputted from the DLL 60 to the reset terminal 51R and the reset terminal 81R of the reset divider 81, thereby resetting the first divider 51 and the reset divider 81 once alone through the use of the rise timing of the first reference clock signal SB1. Consequently, the first divider 51 and the reset divider 81 start division of the output clock signal ST in accordance with the rise timing of the first reference clock signal SB1. Incidentally, the reset switch 90 is turned off after the resetting.

When the number of pulses of the output clock signal ST, which has been counted by the reset divider 81, reaches M/n (e.g., 128), the reset signal SS outputted from the reset divider 81 results in rise timing. Therefore, the switch control circuit 82 turns on the selector switch 92 alone in advance. In doing so, the second divider 52 is reset with the rise timing of the reset signal SS. Namely, the first divider 51 is reset and thereafter the second divider 52 is reset with being delayed by the number of pulses M/n of the output clock signal ST. Thus, the second divided signal SD2 can be set so as to be delayed M/n (e.g., 128) as the number of the pulses of the output clock signal ST with respect to the first divided signal SD1. Thereafter, the switch control circuit 82 turns off the selector switch 92.

Further, when the number of the pulses of the output clock signal ST, which has been counted by the reset divider 81, reaches M/n (e.g., 128), the reset signal SS outputted from the reset divider 81 results in rise timing again. Therefore, the switch control circuit 82 turns on the selector switch 93 alone slightly before such rise timing. In doing so, the third divider 53 is reset with the rise timing of the reset signal SS. Thus, the second divided signal SD2 and third divided signal SD3 can be respectively set so as to be shifted M/n (e.g., 128) as the number of the pulses of the output clock signal ST. Accordingly, the third divided signal SD3 can be set so as to be delayed 2M/n (e.g., 256) as the number of the pulses of the output clock signal ST with respect to the first divided signal SD1. Afterwards, the switch control circuit 82 turns off the selector switch 93.

By sequentially resetting the second through n-th dividers 52 through 5n in order, the j-th dividers 5j (corresponding to the second through n-th dividers 52 through 5n) can be set in such a manner that the j-th divided signals SBj (where j: an integer of 2 to n) rise with being delayed the number of pulses Pj=(j−1)·M/n of the output clock signal ST compared with the rising edge of the first divided signal SD1 as described above. Assuming that n=8 and M=1024, for example, P2=128, P3=256, . . . , P8=896 respectively. Since shifts in divided outputs of the dividers 51 through 5n remain unchanged unless the dividers 51 through 5n are reset, the division timings of the dividers 51 through 5n are set in this way, whereby PLL control can be suitably performed subsequently to their settings.

While the present invention has been described above in line with the illustrated embodiment, the present invention is not limited to the foregoing embodiment. It is needless to say that changes can be suitably made and applied within the scope not departing from the substance thereof.

For example, as the first through n-th phase comparators 11 through in, the examples using the so-called phase/frequency comparators have been shown which compare the input reference clock signals SB1 and the like and the divided signals SD1 and the like and output the up signals SP1u and the like or the down signals SP1d and the like having the pulse widths equivalent to the phase differences therebetween, respectively. However, phase comparators may be used each of which outputs exclusive-ORing of input two signals. In this case, a charge pump is unnecessary. Such a configuration that a binary type phase comparator for determining which one of the phases of input two signals is simply early and indicating the difference in phase therebetween in binary form alone is used as well as a linear type phase comparator for changing a pulse width of a phase difference signal according to a phase difference as in the cases referred to above, and the result of comparison is inputted to a charge pump through an up/down counter, may be adopted.

The known circuit configuration can be used for the VCO 40. For example, a ring oscillator wherein the inputs/outputs of inverting amplifiers of odd-numbered stages are connected in a loop form, a ring oscillator wherein differential amplifiers are connected in the form of plural stages, etc. may be used.

The above-described embodiment has shown, as the divider initial reset circuit 80, one having the selector switches 92 through 9n sequentially turned on and off by the switch control circuit 82 to reset the respective dividers 52 through 5n in addition to the provision of the reset divider 81, the switch control circuit 82 and the reset switch 90. However, the present invention is not limited to such a configuration. A circuit may be used which is configured in such a manner that the respective dividers 52 through 5n can be sequentially reset every rise timings of the reset signal SS of the reset divider 81. For example, n−1 flip-flops are connected so as to input the outputs of their adjacent flip-flops to thereby constitute shift registers of n−1 bits, and the outputs of respective bits are respectively inputted to the reset terminals 52R through 5nR of the respective dividers 52 through 5n. Then data with an initial value as 1 are sequentially shifted every M/n set as the number of pulses of the output clock signal ST with the reset signal SS of the reset divider 81 as a clock signal, whereby the respective dividers 52 through 5n may be sequentially reset.

What is claimed is:

1. A clock multiplying PLL circuit, comprising:
an oscillator circuit for outputting an output clock signal;
first through n-th dividers for dividing the output clock signal and thereby outputting first through n-th divided signals (where n: an integer greater than or equal to 2) respectively, said first through n-th dividers being different in effective transition timings of the outputted first through n-th divided signals from one another;
a reference clock signal generating circuit for generating n types of first through n-th reference clock signals different in phase from one another by using an input reference clock signal; and
first through n-th phase comparators for respectively comparing phases of the i-th reference clock signals and i-th divided signals (where i: an integer of 1 to n),
wherein an oscillation frequency of the output clock signal outputted from the oscillator circuit is changed based on the results of comparisons by the first through n-th phase comparators.

2. A clock multiplying PLL circuit according to claim 1, wherein the first through n-th dividers respectively have the same dividing ratio 1/M (where M: an integer greater than or equal to 2), and
when the number of pulses of the output clock signal outputted from the oscillator circuit is taken as Pj during a period from the effective transition timing of the first divided signal to the effective transition timing of the j-th divided signal (where j: an integer of 2 to n), a phase delay of a j-th reference clock signal when the first reference clock signal is set as the reference, is Pj/M cycles.

3. A clock multiplying PLL circuit according to claim 2, further including divider initial reset means for resetting the first divider once alone with an effective transition timing of the first reference clock signal generated from the reference clock signal generating circuit in wait for the start of the output of the output clock signal from the oscillator circuit after powering the clock multiplying PLL circuit, and resetting the j-th dividers corresponding to the remaining second through n-th dividers once alone, respectively, with timing at which the number of pulses of the output clock signal outputted from the oscillator circuit after the resetting of the first divider reaches the Pj.

4. The clock multiplying PLL circuit according to claim 1, wherein the first through n-th dividers respectively have the same dividing ratio 1/M (where M: an integer greater than or equal to 2),
the number of pulses of an output clock signal outputted from the oscillator circuit is set as M(j−1)/n during a period from the effective transition timing of the first divided signal to an effective transition timing of a j-th divided signal (where j: an integer of 2 to n), and
a phase delay of a j-th reference clock signal when the first reference clock signal is set as the reference, is (j−1)/n cycles.

5. A clock multiplying PLL circuit according to claim 4, further including divider initial reset means for resetting the first divider once alone with an effective transition timing of the first reference clock signal generated from the reference clock signal generating circuit in wait for the start of the output of the output clock signal from the oscillator circuit after powering the clock multiplying PLL circuit, and resetting the j-th dividers corresponding to the remaining second through n-th dividers once alone, respectively, with timing at which the number of pulses of the output clock signal outputted from the oscillator circuit after the resetting of the first divider reaches the M(j−1)/n.

6. A clock multiplying PLL circuit according to claim 5, wherein the divider initial reset means includes a reset divider of a dividing ratio 1/(M/n) reset together with the first divider with the effective transition timing of the first reference clock signal, and sequential reset means for sequentially resetting the second through n-th dividers in accordance with a divided signal of the reset divider.

7. A clock multiplying PLL circuit according to claim 1, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

8. A clock multiplying PLL circuit according to claim 2, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

9. A clock multiplying PLL circuit according to claim 3, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

10. A clock multiplying PLL circuit according to claim 4, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

11. A clock multiplying PLL circuit according to claim 5, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

12. A clock multiplying PLL circuit according to claim 6, wherein the oscillator circuit is a voltage-controlled oscillator, and which further includes,
an up signal adder for adding first through n-th up signals of respective results of comparisons by the first through n-th phase comparators,
a down signal adder for adding first through n-th down signals thereof,
a charge pump for inputting the added up signal and the added down signal, and
a low-pass filter for smoothing a signal outputted from the charge pump and inputting the smoothed output to the voltage-controlled oscillator.

13. A clock multiplying PLL circuit according to claim 1, wherein the reference clock signal generating circuit is a delay locked loop circuit for delaying the reference clock signal and thereby generating the first through n-th reference clock signals.

14. A clock multiplying PLL circuit according to claim 2, wherein the reference clock signal generating circuit is a delay locked loop circuit for delaying the reference clock signal and thereby generating the first through n-th reference clock signals.

15. A clock multiplying PLL circuit according to claim 3, wherein the reference clock signal generating circuit is a delay locked loop circuit for delaying the reference clock signal and thereby generating the first through n-th reference clock signals.

16. A clock multiplying PLL circuit according to claim 4, wherein the reference clock signal generating circuit is a delay locked loop circuit for delaying the reference clock signal and thereby generating the first through n-th reference clock signals.

17. A clock multiplying PLL circuit according to claim 5, wherein the reference clock signal generating circuit is a delay locked loop circuit for delaying the reference clock signal and thereby generating the first through n-th reference clock signals.

18. A clock multiplying PLL circuit according to claim 6, wherein the reference clock signal generating circuit is a delay locked loop circuit for delaying the reference clock signal and thereby generating the first through n-th reference clock signals.

19. A clock multiplying PLL circuit for PLL-controlling an oscillator circuit and outputting an output clock signal having multiplied frequency obtained by multiplying an input reference clock signal, comprising:
n (where n: an integer greater than or equal to 2) dividers having the same dividing ratio and for dividing the output clock signal;
n-pieces of phase comparators paired with the dividers; and
a reference clock signal generating circuit for generating n types of reference clock signals different in phase from one another using the reference clock signal,
wherein each of the phase comparators obtains a result of phase comparison from a phase comparison between each of divided signals outputted from the dividers paired with the phase comparators and any of the n types of reference clock signals, and the oscillator circuit is PLL-controlled by n times for each cycle period of the reference clock signal by use of the result of phase comparison.

20. A clock multiplying PLL circuit for outputting an output clock signal having multiplied frequency obtained by multiplying an input reference clock signal, comprising:
an oscillator circuit; and
a multiple control circuit for performing PLL-control on the oscillator circuit by a predetermined number of times greater than or equal to 2 for each cycle period of the reference clock signal.
